(19) United States
(12) Patent Application Publication
(10) Pub. No.: US 2026/0123407 A1
(43) Pub. Date: Apr. 30, 2026

(54) HEAT DISSIPATION CHANNELS IN A SEMICONDUCTOR PACKAGE

(71) Applicant: Taiwan Semiconductor Manufacturing Company, Ltd., Hsin-Chu (TW)

(72) Inventors: Pei-Hsuan LEE, Tainan City (TW); Chao-Wei LI, Hsinchu City (TW); Yu-Hsiang HU, Hsinchu City (TW); Chien-Hsun LEE, Chu-tung Town (TW); Kathy Wei YAN, Hsinchu (TW)

(21) Appl. No.: 18/931,948

(22) Filed: Oct. 30, 2024

(51) Int. Cl. H01L 23/367; H01L 23/00; H01L 23/373; H01L 23/538; H01L 25/00; H01L 25/18; H10B 80/00

(52) U.S. Cl. CPC H10W 40/22; H10W 90/00; H10B 80/00; H10W 40/251; H10W 70/611; H10W 72/07354; H10W 72/325; H10W 72/334; H10W 72/342; H10W 72/347; H10W 72/353; H10W 72/354; H10W 74/15; H10W 90/401; H10W 90/724; H10W 90/733; H10W 90/734

(57) ABSTRACT

One aspect of the present disclosure pertains to a package structure. The package structure includes a die bonded to a substrate, where a plurality of first channels are formed on a top surface of the die; a lid bonded to the substrate and over the die; and a thermal interface material (TIM) disposed between and contacting the lid and the die, where the thermal interface material fills the first channels.

### PRIORITY DATA

This application claims the benefit of U.S. Provisional Application No. 63/684,179 filed Aug. 16, 2024, the entirety of which is herein incorporated.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

Demands for more power and more condensed chip space (e.g., in high performance computing (HPC) and artificial intelligence (AI) applications) require proportional advancements in thermal management. For example, in HPC and AI applications, a critical issue is the hot spot thermal dissipation of device dies within central processing units (CPUs) and graphical processing units (GPUs). In 2.5D or 3D IC structures, device dies are bonded to a package substrate (e.g., via an interposer) to form semiconductor packages. The heat generated by the device dies during operation needs to be properly dissipated to prevent performance degradation or even physical damage. To dissipate heat, a metal lid may be bonded to the package substrate to engage and take away the heat from the device dies. However, the heat dissipation efficiency in existing semiconductor packages require improvements in order to meet the power demands of data centers running HPC and AI workloads.

Therefore, although existing semiconductor packages have been generally adequate for their intended purposes, they have not been entirely satisfactory in every aspect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion. It is also emphasized that the figures appended illustrate only typical embodiments of this invention and are therefore not to be considered limiting in scope, for the invention may apply equally well to other embodiments. Further, the accompanying figures may implicitly describe features not explicitly described in the detailed description.

FIG. 1 illustrates an integrated circuit (IC) semiconductor package having dies with heat dissipation channels for improved thermal distribution, according to an embodiment of the present disclosure.

FIGS. 2A-2B illustrate top views of dies in FIG. 1, according to various embodiments of the present disclosure.

FIG. 3 illustrates an IC semiconductor package having dies with heat dissipation channels and also a lid with heat dissipation channels for improved thermal distribution, according to an embodiment of the present disclosure.

FIGS. 4A-4B illustrate top views of dies in FIG. 3, according to various embodiments of the present disclosure.

FIG. 5 illustrates an IC semiconductor package having dies with heat dissipation channels and also a lid with heat dissipation channels for improved thermal distribution, according to another embodiment of the present disclosure.

FIG. 6 illustrates a cross-sectional view of an IC semiconductor package with heat dissipation channels, according to an embodiment of the present disclosure.

FIG. 7 illustrates a top view of dies having heat dissipation channels, according to an embodiment of the present disclosure.

FIGS. 8A-8B illustrate top views of dies having heat dissipation channels, according to further embodiments of the present disclosure.

FIG. 9 illustrates a top view of dies having heat dissipation channels, according to a further embodiment of the present disclosure.

FIGS. 10A-10B illustrate dies having a single cavity to dissipate heat, according to an embodiment of the present disclosure.

FIGS. 11A-11B illustrate dies having a plurality of cavities to dissipate heat, according to an embodiment of the present disclosure.

FIGS. 12A-12B illustrate dies having a layered cavity to dissipate heat, according to an embodiment of the present disclosure.

FIG. 13 illustrates a flow chart of a method to form an IC semiconductor package having heat dissipation channels for improved thermal distribution, in portion or in entirety, according to an embodiment of the present disclosure.

FIGS. 14-22 (including FIGS. 20A and 20B) illustrate an IC semiconductor package (or a portion thereof) at intermediate stages of fabrication and processed in accordance with the method of FIG. 13, according to an embodiment of the present disclosure.

FIG. 23 illustrates a flow chart of a method to form an IC semiconductor package having heat dissipation channels for improved thermal distribution, in portion or in entirety, according to another embodiment of the present disclosure.

FIGS. 24 and FIGS. 25A-25C illustrate an IC semiconductor package (or a portion thereof) at intermediate stages of fabrication and processed in accordance with the method of FIG. 23, according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “under,” “below,” “lower,” “above,” “over,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” “substantially,” and the like, the term is intended to encompass numbers that are within a reasonable range including the number described, such as within +/−10% of the number described, or other values as understood by person skilled in the art. For example, the term “about 5 nm” may encompass the dimension range from 4.5 nm to 5.5 nm where manufacturing tolerances associated with depositing the material layer are known to be +/−10% by one of ordinary skill in the art. And when comparing a dimension or size of a feature to another feature, the phrases “substantially the same,” “essentially the same,” “of similar size,” and the like, may be understood to be within +/−10% between the compared features. Further, disclosed dimensions of the different features can implicitly disclose dimension ratios between the different features.

To address the greater thermal loads of high power semiconductor devices in the next-generation data centers, thermal management in backend package technology is one key component in improving energy efficiency. Improved energy efficiency better supports the complex IC requirements of AI, ML, and HPC. As such, the present disclosure provides embodiments of enhanced heat dissipation in semiconductor packaging, thereby facilitating better heat spread and improving energy efficiency. More specifically, the present disclosure describes IC package structures (e.g., semiconductor packages) that have heat dissipation channels formed in dies and/or in a lid. The semiconductor packages may include IC chips (also referred to as dies) in a 2.5D or a 3D IC package configuration (as described later).

In order to direct heat away from device hot spots, thermal interface material (TIM) layer(s) are used to improve heat transfer between a heat source (e.g., an IC chip or die) and a heat sink (e.g., heat-spreading lid). Proper heat transfer is critical so that heat is not trapped causing device failures. To improve heat transfer, the present disclosure describes semiconductor packages having heat dissipation channels that increase the thermal contact between heat-producing dies and a heat sink (e.g., a metal lid). The heat dissipation channels may be formed on top surfaces of the dies to provide a greater interface area between the heat-producing dies and the TIM layer. Heat dissipation channels may also be formed on a bottom surface of a heat-spreading lid to provide a greater interface area between the TIM layer and the heat-spreading lid.

The heat dissipation channels not only provide increased surface area for thermal dissipation; they also provide buffer spaces for thermal expansion of the lid and the dies. In this way, physical stress on the whole package is reduced when thermal load is applied. The TIM layer may be made of an elastic material with high compressibility and high heat resistance (e.g., graphite). When compressed, the TIM layer may conform to the shape of the heat dissipation channels. The TIM layer may also be made of other materials such as metals. The heat dissipation channels may be formed by a laser grooving process, a saw grooving process, a sand-blasting process, a sand-spraying process, or other machining processes. The heat dissipation channels in the dies may be formed in the wafer stage before the dies are bonded to a package substrate, or they may be formed after the dies are bonded to the package substrate. The heat dissipation channels may take the form of elongated channels, cavities, and various regular or irregular shapes.

The various aspects of the present disclosure will now be described in more detail with reference to the figures. Throughout the present disclosure, unless expressly otherwise described, like reference numerals denote like features.

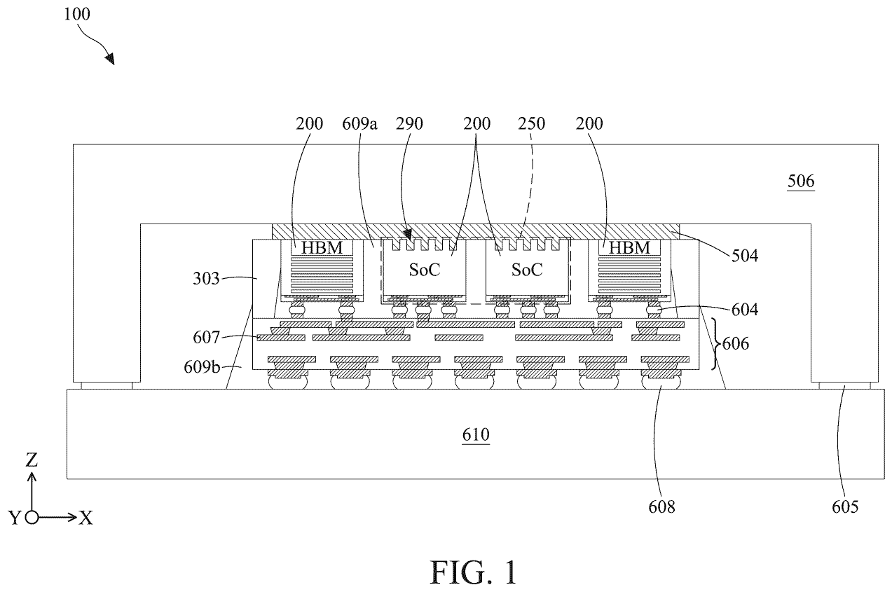

FIG. 1 illustrates an integrated circuit (IC) semiconductor package 100 having dies 200 with heat dissipation channels 290 for improved thermal distribution, according to an embodiment of the present disclosure. The heat dissipation channels 290 may form (or be formed) of a plurality of grooves that cut into a top surface of the dies 200. The heat dissipation channels 290 directly enlarge the contact surface area of the respective dies 200 for better and faster thermal dissipation in high power semiconductor devices. In addition, such channels may help relieve the stress of the whole package. In particular, the heat dissipation channels 290 provide buffer spaces for thermal expansion of the top dies 200, and the TIM layer 504 may be compressed and recovered due to its flexibility.

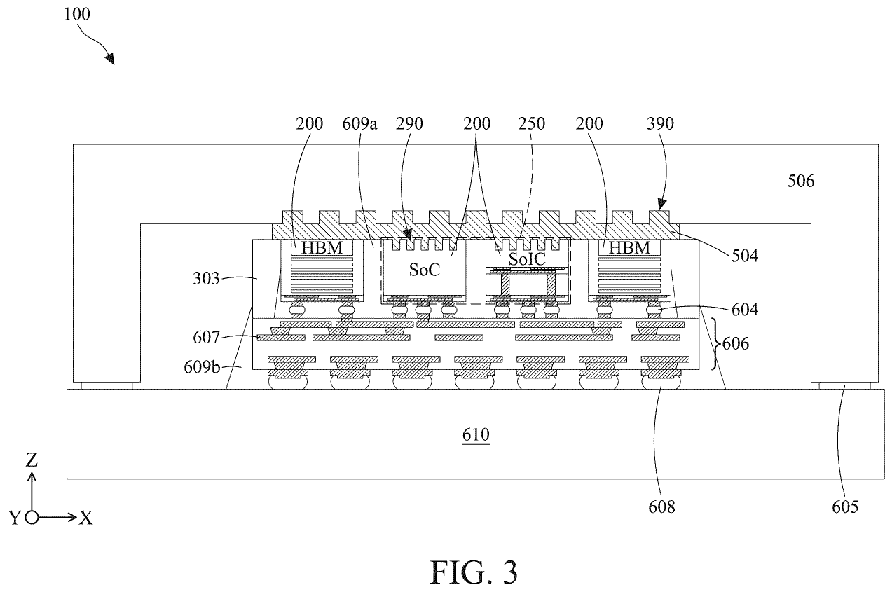

The semiconductor package 100 may include 2.5D and/or 3D IC heterogenous integrated structures. In a 2.5D structure, at least two dies 200 are coupled to a redistribution layer (RDL) structure (e.g., interposer 606) that provides chip-to-chip communication. The at least two dies 200 in a 2.5D structure are not stacked one over another vertically. In a 3D structure, at least two dies 200 are stacked one over another and interact with each other by way of through silicon vias (TSVs). The 2.5D and 3D structures may combine high bandwidth memory (HBM) and system-on-chip (SoC) dies into a single semiconductor package 100. An SoC die combines elements of a computing or electronic system such as CPU, memory, etc., that were originally in separate chips. Some of the SoC dies may be system-on-IC (SoIC) dies (see FIG. 3), which are composite dies having vertically stacked dies. In this way, 2.5D structures that have SoIC dies may also be viewed as 3D structures. Depending on the processes adopted, the 2.5D structure and the 3D structure may have an Integrated Fan-Out (InFO) construction or a Chip-on-Wafer-on-Substrate (CoWoS®) construction.

In the embodiment shown, the semiconductor package 100 includes a package substrate 610, an interposer 606 over the package substrate 610, multiple dies 200 over the interposer 606, a TIM layer 504 over the dies 200, and a lid 506 over the TIM layer 504. The dies 200 are bonded to the interposer 606 via micro-bumps 604, and the interposer 606 is bonded to the package substrate 610 via controlled collapse chip connection (C4) bumps 608. The dies 200 are laterally surrounded by an underfill 609a that lands on the interposer 606. The interposer 606 is laterally surrounded by an underfill 609b that lands on the package substrate 610. A molding compound 303 is disposed adjacent and surrounds the edge dies 200 (e.g., the HBM dies) and lands on the interposer 606. These and other various features are described in more detail below.

The package substrate 610 generally refers to a wafer or semiconductor structure that acts as a carrier base for an IC package. This carrier base may also be generally referred to as a base substrate, a substrate underlayer, or the like. In an embodiment, the package substrate 610 includes a semiconductor substrate formed of silicon, silicon germanium, silicon carbon, or the like. The package substrate 610 may have various package components mounted thereon, such as one more interposers 606, one or more dies 200, and/or one or more other active or passive chip devices. The package substrate 610 may further include redistribution layers formed therein, and the redistribution layers route signals from die components (e.g., dies 200) onto a printed circuit board (PCB) (not shown).

The semiconductor package 100 may be part of a bigger IC structure. For example, the semiconductor package 100 may be mounted onto a PCB (not shown). In this case, the package substrate 610 may include a ball-grid array (BGA) structure on its back side. The BGA structure includes solder joints that may bond one or more semiconductor packages 100 onto the PCB. The PCB may include multiple other IC components mounted thereon, thereby forming a processor, a controller, a memory unit, or other electronic modules.

The interposer 606 generally refers to a redistribution layer (RDL) structure that electrically connects one or more dies 200 to each other and/or to another structure (e.g., package substrate 610). The interposer 606 may be a silicon interposer or an organic interposer. The interposer 606 may include conductive traces 607 that route electrical signals between dies 200 and/or between dies 200 and the package substrate 610. The conductive traces 607 may include various metal lines extending laterally and various metal vias extending vertically. The metal vias vertically connects the metal lines. The conductive traces 607 are embedded in in one or more passivation layers. The passivation layers are insulating layers for isolating different signal paths.

The interposer 606 is bonded and electrically connected to the package substrate 610 via one or more C4 bumps 608. The C4 bumps 608 are disposed on a back side of the interposer 606. The C4 bumps 608 are interconnect bumps and may include solder bumps or copper pillar (CuP) bumps. The solder bumps may include tin, lead, and/or silver, and the CuP bumps may include a copper pillar having a solder cap at the end. The solder cap may be made of tin, lead, and/or silver. The C4 bumps 608 may land on bonding pads of the package substrate 610.

The dies 200 are bonded to and electrically connected to the interposer 606 via one or more micro-bumps 604. The micro-bumps 604 are disposed on a back side of the dies 200. Like the C4 bumps 608, the micro-bumps 604 are interconnect bumps and may include solder bumps or copper pillar (CuP) bumps. The solder bumps may include tin, lead, and/or silver, and the CuP bumps may include a copper pillar having a solder cap at the end. The solder cap may be made of tin, lead, and/or silver. The difference between the C4 bumps 608 and the micro-bumps 604 is that the micro-bumps 604 may have a smaller width in the x and/or y direction. The micro-bumps 604 may be attached to landing pads of the dies 200 on one side and landing pads of the interposer 606 on the other side. The landing pads of the dies 200 may be part of an aluminum pad layer. And the aluminum pad layer may be part of (or extend from) an RDL of the dies 200.

FIG. 1 illustrates four dies 200 disposed along the x direction, however in other embodiments, more or less dies 200 may be present. Multiple dies 200 may also be disposed along the y direction (not shown). The dies 200 may be formed of various active and/or passive devices (e.g., transistor devices, resistors, capacitors, carrier substrate, etc.). In the embodiment shown, two middle SoC dies 200 are laterally disposed between two HBM dies 200, but the disclosure is not limited thereto. For the present embodiments, the dies 200 may be SoC dies, SoIC dies, logic dies, application specific integrated circuit (ASIC) dies, HBM dies, or other types of dies/chips. In the embodiment shown, the dies 200 are disposed adjacent to each other in the lateral direction. In another embodiment, the dies 200 may be stacked on top of each other in the vertical direction. In yet another embodiment, the dies 200 may be disposed adjacent each other and also stacked on top of each other to form various integrated stacked structures.

Each of the dies 200 may include a device layer sandwiched between various IC layers and components (e.g., sandwiched between a frontside interconnect structure and a backside interconnect structure). The device layer is where device-level features such as transistor devices are formed. The transistor devices may be logic devices, memory devices, or the like. Each of the transistor devices includes a channel region between source/drain (S/D) regions and a gate stack over the channel regions. The device layer may further include other device-level features such as S/D contacts, S/D vias, gate contacts, and/or gate vias, each of which may electrically connect the S/D regions and/or the gate stacks to a higher or lower material layer of the dies (e.g., frontside and/or backside interconnect structures). The dies 200 may include a frontside interconnect structure over the device layer and a backside interconnect structure under the device layer. The frontside and backside interconnect structures may include metal lines and vias embedded in intermetal dielectric (IMD) layers, and the metal lines and vias route signals to and from the transistor devices in the device layer. In an embodiment, as part of (or separate from) the dies 200, a bonding layer is disposed over the frontside interconnect structure, and a carrier substrate is disposed over the bonding layer. For example, the bonding layer and the carrier substrate (e.g., made of silicon) are formed to provide structural support when forming the backside interconnect structure.

In the embodiment shown, some of the dies 200 (e.g., SoC dies) include heat dissipation channels 290 while other dies 200 (e.g., HBM dies) do not. For example, some of the dies 200 (e.g., SoC dies) require greater processing power requirements than other dies 200 (e.g., HBM dies). The dies 200 that require greater processing power generate more heat and require better thermal control. For example, the dies 200 that require greater processing power (e.g., SoC dies) are those that perform more computationally intensive tasks, such as high power or high speed logic or memory devices. Whereas the dies 200 that require less processing power (e.g., HBM dies) are those that perform less computationally intensive tasks, such as low power or low speed logic or memory devices. As such, the heat dissipation channels 290 may be selectively formed to support dies 200 that demand greater thermal control (e.g., SoC dies).

The dies 200 without heat dissipation channels 290 may have a planar (or substantially planar) top surface, whereas the dies 200 with heat dissipation channels 290 do not (due to modifications to the die top surface). In the embodiment shown, the heat dissipation channels 290 create a plurality of grooves that cut into a top surface of the respective dies 200. The grooves allow for greater surface contact area to increase thermal contact between the dies 200 and the TIM layer 504. In the embodiment shown, the bottom surface of the grooves are below the top surface of dies 200 without the heat dissipation channels 290.

The underfill 609a and 609b are encapsulants that provide structural and mechanical support between the package substrate 610 and the interposer (see underfill 609b) and between the interposer and the dies 200 (see underfill 609a). The underfill 609a and 609b also mechanically strengthen and surround the micro-bumps 604 and the C4 bumps 608. In an embodiment, the underfill 609a and 609b may be made of composite material such as an epoxy polymer. In an embodiment, the underfill 609a and 609b may be a liquid encapsulant such as epoxy resins infused with silica particles. The molding compound 303 lands on the interposer 606 and is disposed along sidewalls of the underfill 609a and/or the edge dies 200. The molding compound surrounds the underfill 609a to provided additional structural support to the dies 200 encapsulated by the underfill 609a. The molding compound 303 may include similar materials as the underfill 609a and underfill 609b. In an embodiment, the molding compound includes epoxy resins, phenolic hardeners, silicas, catalysts, pigments, and/or mold release agents. In some embodiments, the molding compound 303 are more structurally rigid than the underfill 609a and 609b for securing onto the interposer 606. The molding compound 303, underfill 609a, and the underfill 609b collectively prevents mechanical fatigue by providing stress redistribution.

Still referring to FIG. 1, the semiconductor package 100 includes one or more TIM layers 504 disposed over the dies 200. The TIM layer 504 lands on a top surface of the molding compound 303, the dies 200, and the underfill 609a. In embodiments where there are multiple stacked dies 200 (not shown), additional TIM layers 504 may be disposed between the stacked dies 200. In any case, a TIM layer 504 is disposed on a topmost surface of the topmost dies 200. The TIM layer 504 acts as a heat conduit and distributor on a front side of the respective dies 200. The TIM layer 504 may be configured to uniformly and effectively direct heat away from the respective dies 200 to the lid 506.

In an embodiment, the TIM layer 504 is a graphite TIM layer 504. For example, the graphite TIM layer 504 includes a graphite filler embedded in a base material, where the graphite filler has a vertically or horizontally laminated structure. The base material of the graphite TIM layer 504 may be a polymeric material, a resin, or other suitable materials. The graphite TIM layer 504 is not adhesive and stays in place between the dies 200 and the lid 506 by compression force and/or by assistance of another adhesive TIM material (not shown). The graphite TIM layer 504 are highly compressible and elastic. As such, the graphite TIM layer 504 can conform to, and be filled in, the heat dissipating channels 290 when the lid 506 is attached to the package substrate 610.

In an embodiment, the TIM layer 504 may include other filler materials. The TIM layer 504 may include a polymer, resin, or epoxy as a base material, and a filler to improve its thermal conductivity. The filler may include a dielectric filler such as aluminum oxide, magnesium oxide, aluminum nitride, boron nitride, and diamond powder. Alternatively, the filler may include a metal filler such as silver, copper, aluminum, or the like. In further embodiments, the TIM layer 504 may include liquid metal or viscous metal. The TIM layer 504 may also include adhesive materials. In any case, the TIM layer 504 can conform to, and be filled in, the heat dissipating channels 290 when the lid 506 is attached to the package substrate 610 (or even before the lid 506 is attached).

As shown, the TIM layer 504 may seep into dies 200 having the heat dissipating channels 290. For these dies 200, the TIM layer 504 has a greater thermal interface area than the dies 200 without the heat dissipating channels 290. As such, greater thermal flow is made possible for directing heat to the lid 506. Also as shown, a bottom surface of the TIM layer 504 share a coplanar surface with top surfaces of the HBM dies 200.

Still referring to FIG. 1, the semiconductor package 100 further includes a lid 506 disposed on a top surface of the TIM layer 504. The lid 506 may be mounted onto the package substrate 610 through base adhesive joints 605 or a lid seal glue layer. The base adhesive joints 605 (or lid seal glue layer) glue the lid 506 onto the package substrate 610. The base adhesive joints 605 be made of any suitable material (e.g., epoxy, adhesive tapes, etc.).

The lid 506 is also referred to as a heat sink. Alternatively, a separate heat sink may be further attached to the lid 506. The lid 506 may be a metal cap that acts as a cover for the semiconductor package 100. The lid 506 may surround device components (e.g., dies 200, interposer 606, etc.) of the semiconductor package 100. Besides acting as a cover, the lid 506 also acts as a heat spreader and heat absorber to absorb any heat dissipated from components of the dies 200. The lid 506 absorbs heat from the dies 200 through the TIM layer 504. The lid 506 is formed of a metal or a metal alloy, which has a high thermal conductivity, for example, higher than about 100 W/m/K. For example, the lid may be formed of a metal, or a metal alloy selected from Al, Cu, Ni, Co, stainless steel, and alloys thereof.

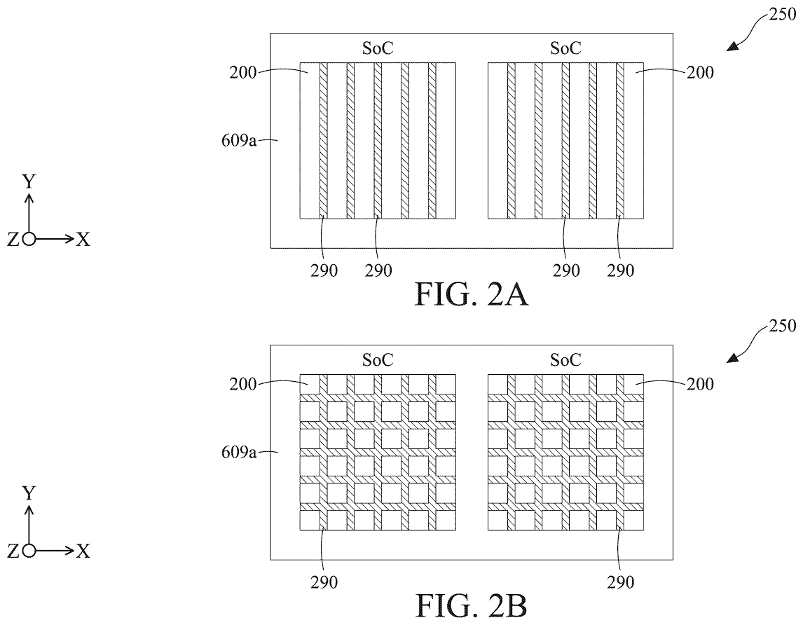

FIGS. 2A-2B illustrate top views of dies 200 having heat dissipation channels 290, according to various embodiments of the present disclosure. As an example, FIGS. 2A-2B illustrate top views of a package area 250 highlighted in FIG. 1 (shown in the dashed box). The dies 200 are surrounded and separated from each other by the underfill 609a from a top view. The heat dissipation channels 290 may be formed by a mechanical saw/laser grooving process to form a series of elongated trenches that cut into top surfaces of the dies 200. The grooves may be formed in a die frontside or a die backside depending on how the dies 200 are processed. The grooves may cut into a carrier substrate portion of the dies.

Referring to the embodiment in FIG. 2A, a plurality of heat dissipation channels 290 extend lengthwise along the y direction over top surfaces of the dies 200 (e.g., SoC dies). Such configuration may be adopted in rectangular packages/dies with an elongated side, where the heat dissipation channels extend along the elongated side of the dies 200. The plurality of heat dissipation channels may also relieve thermal stress along the x direction due to the grooves providing buffer spaces for thermal expansion along the x direction. In alternative embodiments, the plurality of heat dissipation channels 290 extend lengthwise along the x direction instead of the y direction. In any case, heat dissipation channels may be grooves in the form of a set of parallel lines that extend across the top surface of the respective dies 200.

Referring to the embodiment in FIG. 2B, a plurality of heat dissipation channels 290 extend lengthwise along both the x and y directions to form cross-shaped channels. Such configuration may be adopted in square or concentric packages/dies. The plurality of heat dissipation channels 290 provide even greater thermal contact and thermal stress relief than the embodiment shown in FIG. 2A. In this embodiment, the heat dissipation channels may be grooves in the form of a set of crisscross lines that extend across the top surface of the respective dies 200.

FIG. 3 illustrates an IC semiconductor package 100 having dies 200 with heat dissipation channels 290 and also a lid 506 with heat dissipation channels 390 for improved thermal distribution, according to an embodiment of the present disclosure. FIG. 3 illustrates a similar IC semiconductor package 100 as the one shown in FIG. 1, and the similar features are not described again for the sake of brevity. One difference is that one of the dies 200 may be an SoIC die, which as previously described, may be a composite die having multiple dies vertically stacked. Another difference is that not only are heat dissipation channels 290 formed in top surfaces of the respective dies 200, heat dissipation channels 390 are also formed in the bottom surface of the lid 506. This allows for further thermal surface contact area and improved heat dissipation. Forming heat dissipation channels 390/290 on the lid 506 and the top dies 200 (e.g., SoC, SoIC, etc.) increases the surface area for thermal dissipation (i.e., in contact with the TIM layer 504). In addition, such channels may help to relieve the stress of the whole package. In particular, the channels provide buffer spaces for thermal expansion of the lid 506 and the top dies 200, and the TIM layer 504 may be compressed and recovered due to its flexibility.

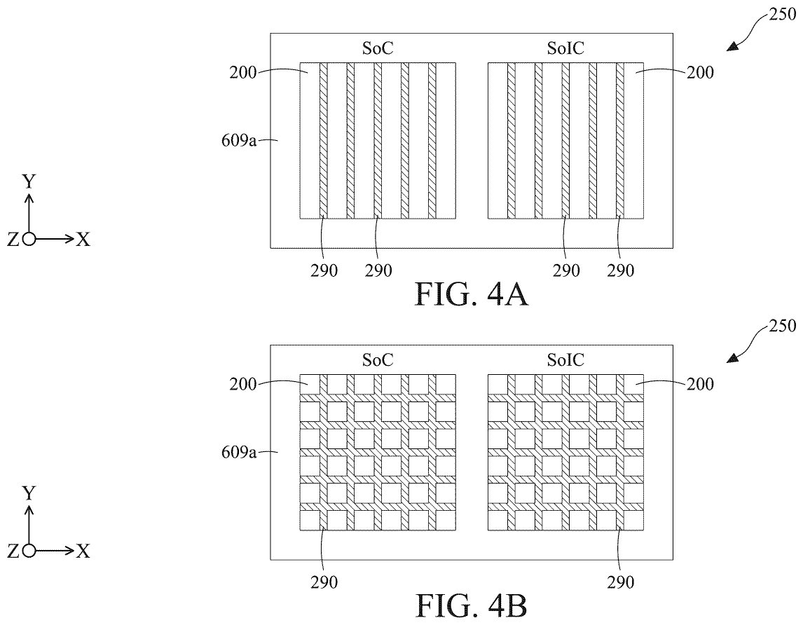

FIGS. 4A-4B illustrate top views of dies 200 having heat dissipation channels 290, according to various embodiments of the present disclosure. As an example, FIGS. 4A-4B illustrate top views of a package area 250 highlighted in FIG. 3 (shown in the dashed box). The dies 200 are surrounded and separated from each other by the underfill 609a from a top view. The heat dissipation channels 290 may be formed by a mechanical saw/laser grooving process to form a series of elongated trenches that cut into top surfaces of the dies 200. Although not shown, the heat dissipation channels 390 in the lid 506 may also be similarly formed by a mechanical saw/laser grooving process.

Referring to the embodiment in FIG. 4A, a plurality of heat dissipation channels 290 extend lengthwise along the y direction over top surfaces of the dies 200 (e.g., SoC dies). Such configuration may be adopted in rectangular packages/dies with an elongated side, where the heat dissipation channels extend along the elongated side of the dies 200. The plurality of heat dissipation channels may also relieve thermal stress along the x direction due to the grooves providing buffer spaces for thermal expansion along the x direction. In alternative embodiments, the plurality of heat dissipation channels 290 extend lengthwise along the x direction instead of the y direction. In any case, heat dissipation channels may be grooves in the form of a set of parallel lines that extend across the top surface of the respective dies 200.

Referring to the embodiment in FIG. 4B, a plurality of heat dissipation channels 290 extend lengthwise along both the x and y directions to form cross-shaped channels. Such configuration may be adopted in square or concentric packages/dies. The plurality of heat dissipation channels 290 provide even greater thermal contact and thermal stress relief than the embodiment shown in FIG. 4A. In this embodiment, the heat dissipation channels may be grooves in the form of a set of crisscross lines that extend across the top surface of the respective dies 200.

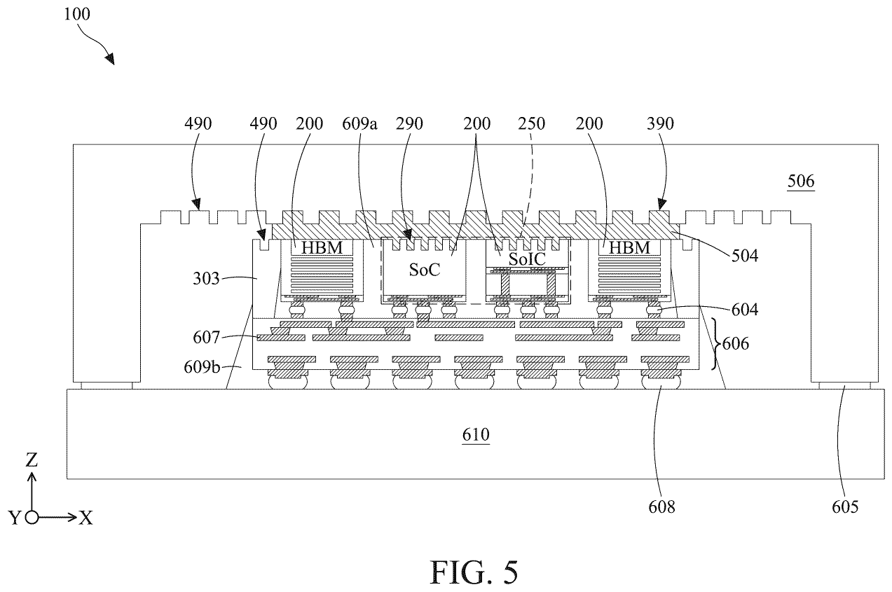

FIG. 5 illustrates an IC semiconductor package 100 having dies 200 with heat dissipation channels 290 and also a lid 506 with heat dissipation channels 390 for improved thermal distribution, according to another embodiment of the present disclosure. FIG. 5 illustrates a similar IC semiconductor package 100 as the one shown in FIG. 3, and the similar features are not described again for the sake of brevity. One difference is that additional heat dissipation channels 490 may be formed in peripheral areas outside the top dies 200. These heat dissipation channels 490 may be formed in portions of the lid 506 laterally beyond the edge dies 200 and/or in the molding compound 303. These channels are at the outer die perimeters and may be used for containing compressed TIM layer(s) 504 and reducing the TIM loss. In addition, such configuration may further relieve the stress by providing more buffer space for thermal expansion of the package.

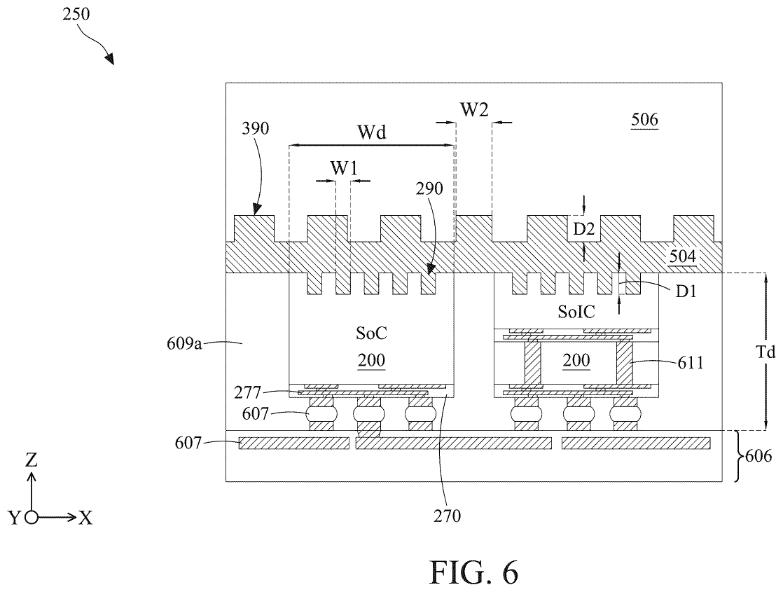

FIG. 6 illustrates a cross-sectional view of an IC semiconductor package 100 with heat dissipation channels 290/390, according to an embodiment of the present disclosure. As an example, FIG. 6 illustrates a cross-sectional view of the package area 250 highlighted in FIG. 3 (shown in the dashed box). In the embodiment shown, the dies 200 are bonded and electrically connected to the interposer 606 (or conductive traces 607 thereof) through bottom RDLs 270 and micro-bumps 604. Specifically, each dic 200 may include a bottom RDL 270 having conductive traces 277, and electrical signals are routed from the RDL 270 to the interposer 606 via the bonded connection at the micro-bumps 604. The respective RDLs 270 may include landing pads as part of an aluminum pad layer. The micro-bumps 604 may be attached to landing pads of the RDLs 270 on one side and landing pads of the interposer 606 on the other side. Note that for vertically stacked die structures (e.g., SoIC dies), through-silicon-vias 611 (TSVs) may be used to vertically route signals between stacked dies. As shown, the TSVs 611 electrically connect between RDLs 270 of the different stacked dies as part of a die 200. The underfill 609a surrounds the dies 200 and the micro-bumps 604.

Still referring to FIG. 6, heat dissipation channels 290 are formed over top surfaces of the dies 200 (e.g., as grooves or dips that cut into the dies 200). The heat dissipation channels 290 are filled by portions of the TIM layer 504. The heat dissipation channels 290 have a channel depth D1 in the z direction and a channel width W1 in the x direction. The dies 200 have a die thickness Td in the z direction and a die width Wd in the x direction. In the embodiment shown, the die thickness Td may encompass a thickness of the micro-bumps 604 and/or any landing pads attached thereto. As such, the die thickness Td may be a thickness of the underfill 609a. In an embodiment, the ratio of the channel depth D1 to the die thickness Td ranges between about 0.7% to about 75%, depending on the size or type of the dies 200 (e.g., SoC or SoIC). For example, to avoid cutting into device portions of the dies 200, the heat dissipation channels 290 for SoIC dies 200 may have a smaller channel depth D1 than that of the SoC dies 200. This is because the SoIC dies 200 are stacked die structures which may have less real estate to form heat dissipation channels 290. In an embodiment, the channel depth D1 may be 5 μm or less. In an embodiment, the die thickness Td may be about 700 μm. In an embodiment, the ratio of the channel width W1 to the die width Wd ranges between about 0.01% to about 90%, depending on the size or type of the dies 200 (e.g., SoC or SoIC). In an embodiment, for TIM layers 504 with superior filling capabilities (i.e., able to fill channels with high aspect ratio), the ratio of the channel width W1 to the die width Wd is less than about 5%. This is because when the ratio is less than about 5%, a greater amount of heat dissipation channels 290 may be formed for maximized thermal contact (e.g., by taking advantage of the TIM layer 504 that can fill up smaller spaces). However, in an embodiment, for TIM layers 504 with weaker filling capabilities (e.g., metal TIMs unable able to fill channels with high aspect ratio), the ratio of the channel width W1 to the die width Wd is greater than about 10%. This is because the channel width W1 needs to be larger to ensure proper fill and contact between the die 200 and the TIM layer 504 to avoid voids or defects due to weaker filling capabilities of the TIM layer 504. In an embodiment, the channel width W1 may be 10 μm or less. In an embodiment, the die width Wd may be about 30 mm.

Still referring to FIG. 6, heat dissipation channels 390 are formed over a bottom surface of the lid 506 (e.g., as grooves or dips that cut into the lid 506). The heat dissipation channels 390 are filled by portions of the TIM layer 504. The heat dissipation channels 390 have a channel depth D2 in the z direction and a channel width W2 in the x direction. In an embodiment, the ratio of the channel depth D2 to the die thickness Td ranges between about 5% to about 200%. In an embodiment, the ratio of the channel width W2 to the die width Wd ranges between about 0.05% to about 100%. The dimensions of the heat dissipation channels 390 in the lid 506 are not strictly regulated since it may not be cost-effective to finely form the channels in the lid 506, especially if the heat dissipation channels 290 are already present.

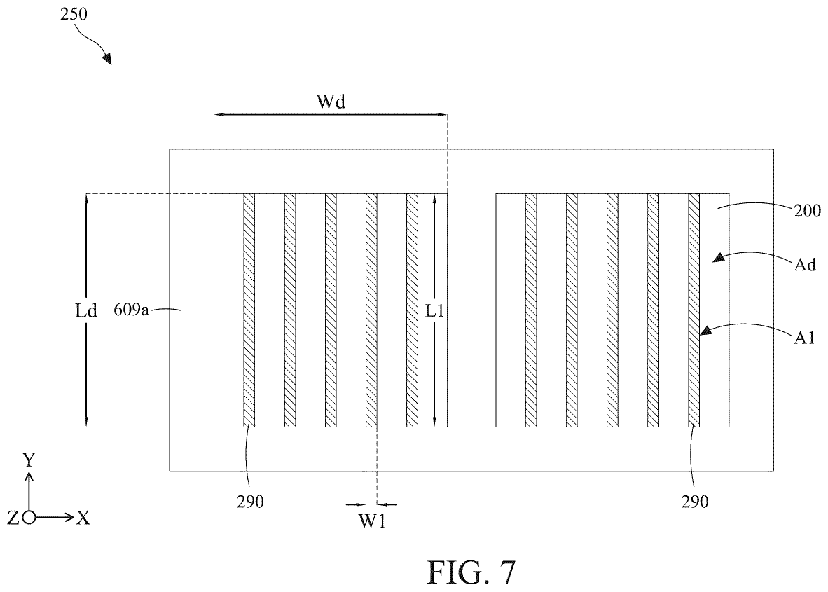

FIG. 7 illustrates a top view of dies 200 having heat dissipation channels 290, according to an embodiment of the present disclosure. As an example, FIG. 7 illustrates a top view of the package area 250 highlighted in FIG. 3 (shown in the dashed box). FIG. 7 illustrates the die width Wd and channel width W1 in a top view. FIG. 7 further a die length Ld and a channel length L1 along the y direction. In an embodiment, the channel length L1 is greater than the channel width W1. In an embodiment, the channel length L1 is substantially the same as the die length Ld. In an embodiment, the die length Ld is substantially the same as the die width Wd. Also as shown, the dies 200 may span a total die area Ad, and the heat dissipation channels 290 may collectively span a channel area A1. In an embodiment, a ratio of the channel area A1 to the total die area Ad ranges between about 5% to about 90%, so as to effectively increase the contact area between the TIM layer 504 and the dies 200.

Although not shown, the sizes or shapes of the heat dissipation channels 390 in the lid 506 may be the same or different as the heat dissipation channels 290, depending on the warpage and expansion of the lid 506 and the dies 200 under various temperatures. The present disclosure contemplates any configuration of the heat dissipation channels 290/390 to enhance thermal dissipation, relieve thermal stress, and reduce TIM loss during any deformation of the semiconductor package 100.

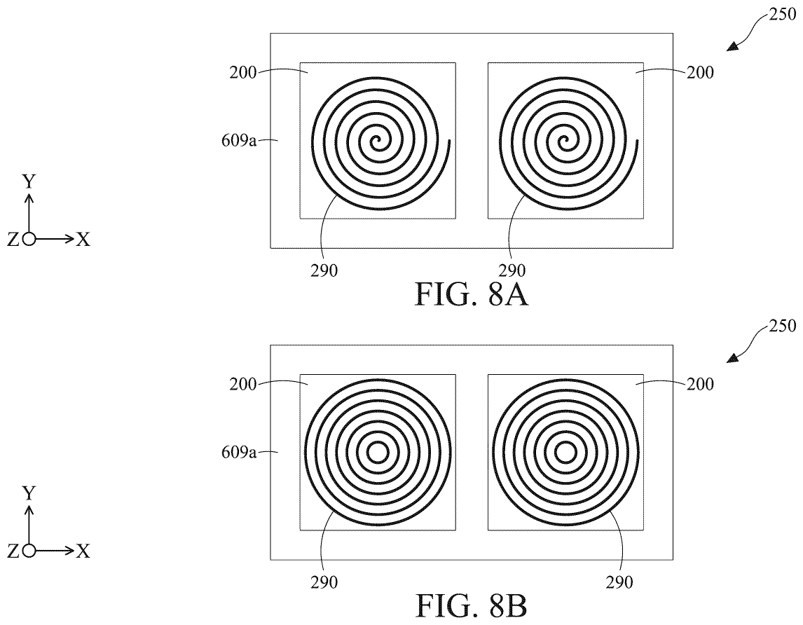

FIGS. 8A-8B illustrate top views of dies 200 having heat dissipation channels 290, according to further embodiments of the present disclosure. Note that in the embodiments of FIGS. 8A-8B, the heat dissipation channels 290 of the dies 200 (and even the heat dissipation channels 390 the lid 506) may be formed in various shapes, such as lines, curves, triangle, circle, quadrilateral, starburst, any regular or irregular shape. It should be noted that the channels may be distributed locally or universally in the lid 506 and the top dies 200. Such channels may be formed using saw/laser grooving processes as described previously. In the embodiments shown, the heat dissipation channels 290/390 have a spiral shape (FIG. 8A) or a concentric circle shape (FIG. 8B).

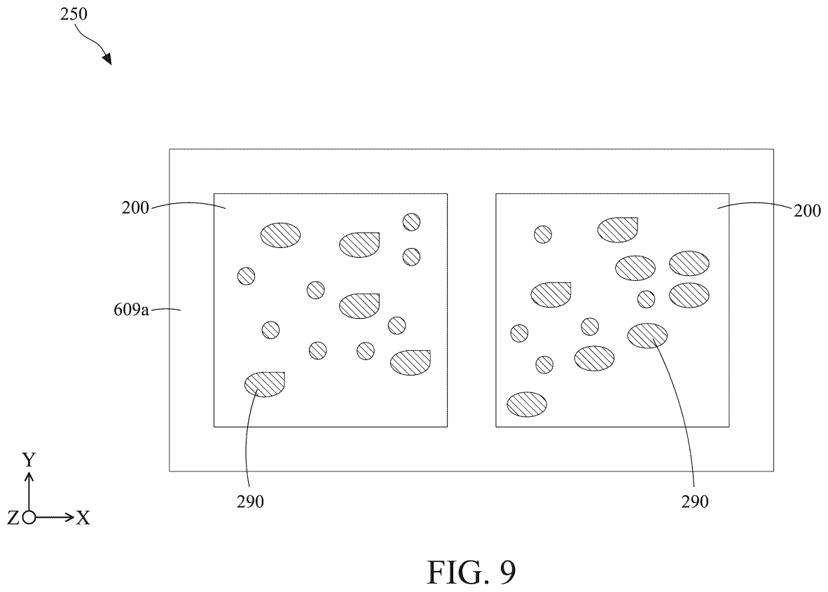

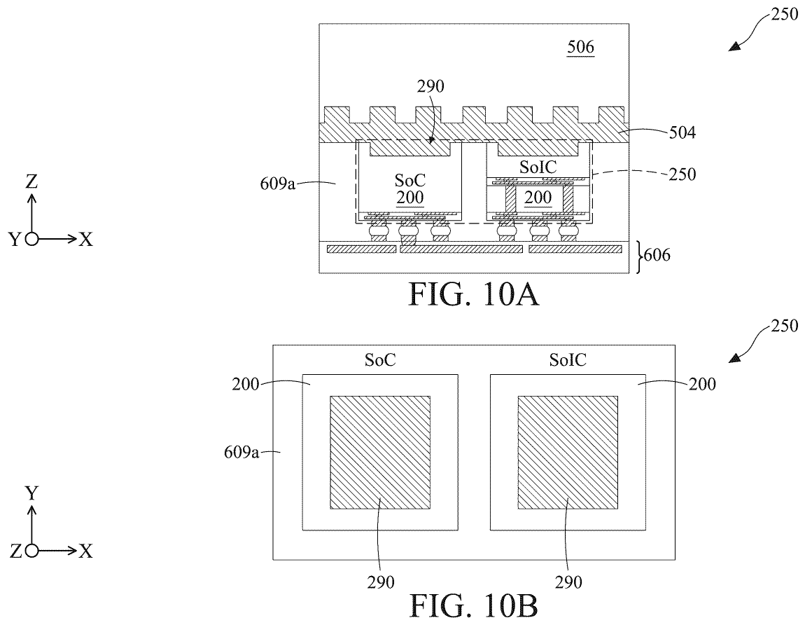

FIG. 9 illustrates a top view of dies 200 having heat dissipation channels 290, according to a further embodiment of the present disclosure. In this embodiment, instead of forming deliberate line channels (FIG. 4A), cross-shaped channels (FIG. 4B), spiral channels (FIG. 8A), concentric circle channels (FIG. 8B), and cavity channels (FIGS. 10-12) by saw/laser grooving processes, channels having random patterns (regular or irregular) may be formed on the top dies 200 using sand-blasting process (i.e., forming recesses) or sand-spraying process (i.e., forming protrusions). In the same way, the contact area between the TIM and the top dies 200 may be increased, improving the thermal dissipation of the semiconductor package 100.

FIGS. 10A-10B illustrate dies 200 having a single cavity to dissipate heat, according to an embodiment of the present disclosure. FIG. 10A illustrates a cross-sectional view having a package area 250 (shown by the dashed box). FIG. 10B illustrates a top view of the package area 250 in FIG. 10A. As shown, the single cavity may be a square or a rectangular cavity. Specifically, the single cavity represents a single heat dissipation channel 290 that may span more than 70% the area of the dies 200 from a top view. This accommodates difficulties in filling certain TIMs into channels with high aspect ratio. For example, for metal TIMs, it may be difficult to fill the channels with high aspect ratio, causing voids or defect in the channels, thereby degrading the thermal dissipation. To solve such issue, a bigger cavity may be formed on the dies for disposing the metal TIM more smoothly, which helps to ensure the cavity is filled with the metal TIM, minimizing the voids or defect in the cavity.

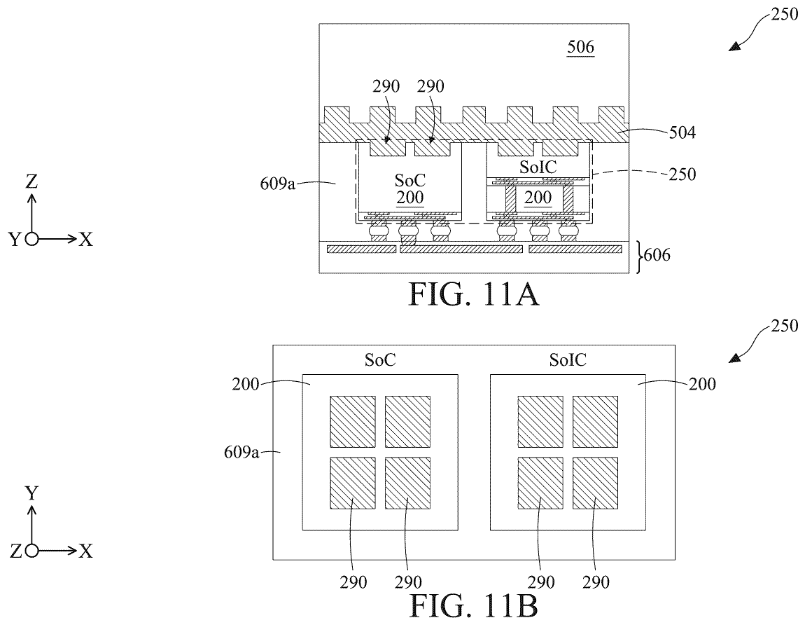

FIGS. 11A-11B illustrate dies 200 having a plurality of cavities to dissipate heat, according to an embodiment of the present disclosure. FIG. 11A illustrates a cross-sectional view having a package area 250 (shown by the dashed box). FIG. 11B illustrates a top view of the package area 250 in FIG. 11A. FIGS. 11A-11B are similar to FIGS. 10A-10B, except that multiple cavities may be formed on the dies 200 for disposing the metal TIM (or other TIMs) that may be difficult to fill channels with high aspect ratio. Such configuration may help to increase the contact area between the metal TIM and the dies 200 compared to the embodiments of FIGS. 10A-10B, further improving the thermal dissipation of the package. The multiple cavities represent multiple heat dissipation channel 290 that may collectively span more than 70% the area of the die from a top view.

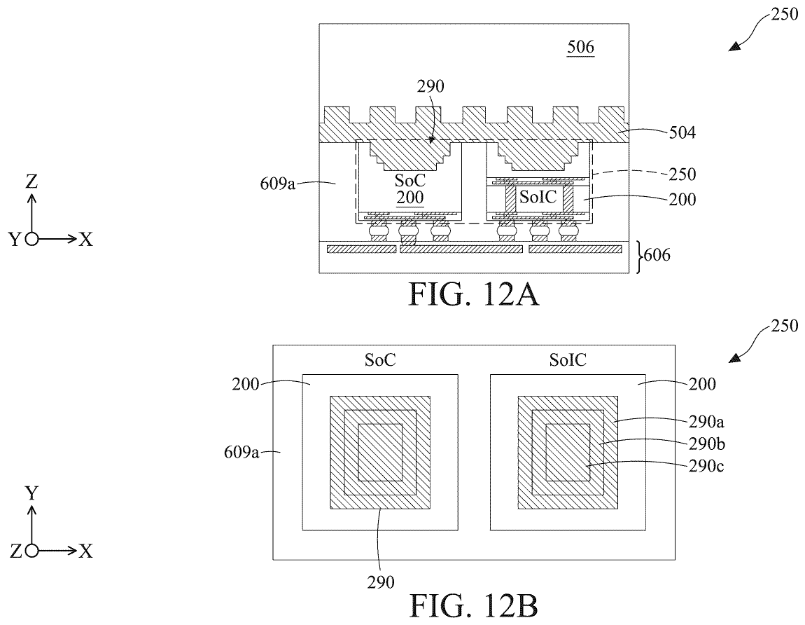

FIGS. 12A-12B illustrate dies having a layered cavity to dissipate heat, according to an embodiment of the present disclosure. FIG. 12A illustrates a cross-sectional view having a package area 250 (shown by the dashed box). FIG. 12B illustrates a top view of the package area 250 in FIG. 12A. FIGS. 12A-12B are similar to FIGS. 10A-10B, except that multi-layered cavities may be formed on the dies for disposing the metal TIM (or other TIMs) that may be difficult to fill channels with high aspect ratio. Such configuration may help to increase the contact area between the metal TIM and the dies 200 compared to the embodiments of FIGS. 10A-10B, further improving the thermal dissipation of the package. The depth and location of the multi-layered cavities may depend on the structure of the dies. The layered approach also creates more surface area for heat dissipation. The multiple cavities represent multiple heat dissipation channel 290 that may collectively span more than 70% the area of the die from a top view. In the embodiment shown, a first cavity (e.g., heat dissipation channel 290c) is formed within a second cavity (e.g., heat dissipation channel 290b), and the second cavity (e.g., heat dissipation channel 290b) is formed within a third cavity (e.g., heat dissipation channel 290a), and the third cavity is greater in area than the second cavity, and the second cavity is greater in area than the first cavity.

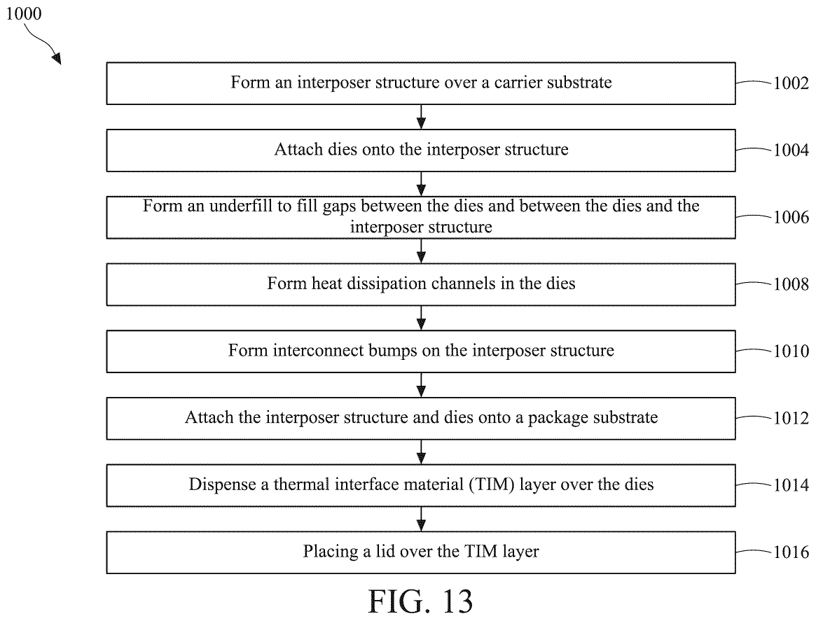

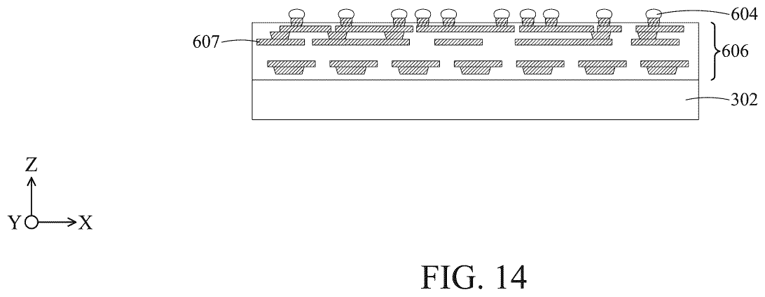

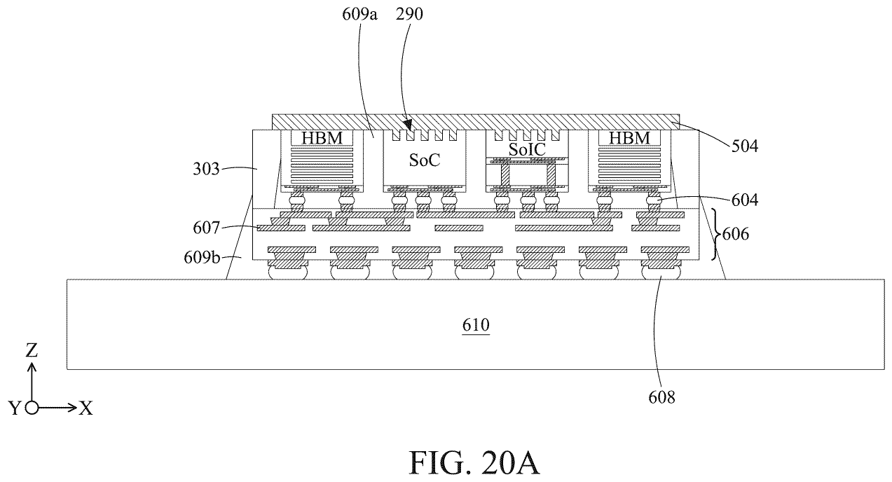

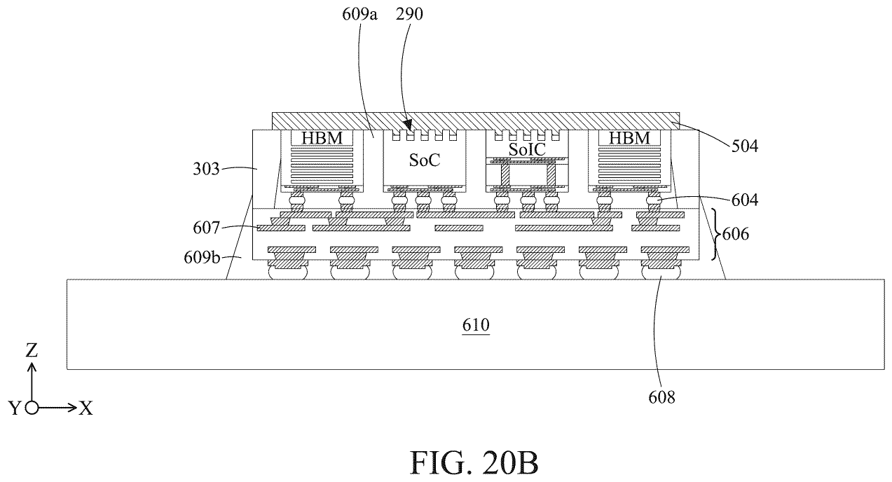

FIG. 13 illustrates a flow chart of a method 1000 to form an IC semiconductor package 100 having heat dissipation channels 290 for improved thermal distribution, in portion or in entirety, according to an embodiment of the present disclosure. FIGS. 14-22 (including FIGS. 20A and 20B) illustrate an IC semiconductor package 100 (or a portion thereof) at intermediate stages of fabrication and processed in accordance with the method of FIG. 13, according to an embodiment of the present disclosure. Method 1000 is merely an example and is not intended to limit the present disclosure to what is explicitly illustrated. Additional steps can be provided before, during and after method 1000 and some steps described can be replaced, eliminated, or moved around for additional embodiments of the method. Not all steps are described herein in detail for reasons of simplicity. Method 1000 is described below in conjunction with FIGS. 14-22 (including FIGS. 20A and 20B). Similar features previously described may equally apply to features shown in FIGS. 14-22. As such, not all features in FIGS. 14-22 are described herein in detail for reasons of simplicity.

Referring to FIG. 14, the method 1000 at operation 1002 forms an interposer structure (e.g., interposer 606) over a carrier substrate 302. The carrier substrate 302 may be a silicon substrate. The interposer structure may be temporarily bonded to the carrier substrate 302 for structural support, and the carrier substrate 302 may be debonded in a later step. The interposer structure includes passivation structures surrounding and isolating conductive traces 607 (such as vias, metal lines, and/or landing pads). The interposer structure further includes micro-bumps 604 formed thereover for bonding to other external structures (e.g., dies 200).

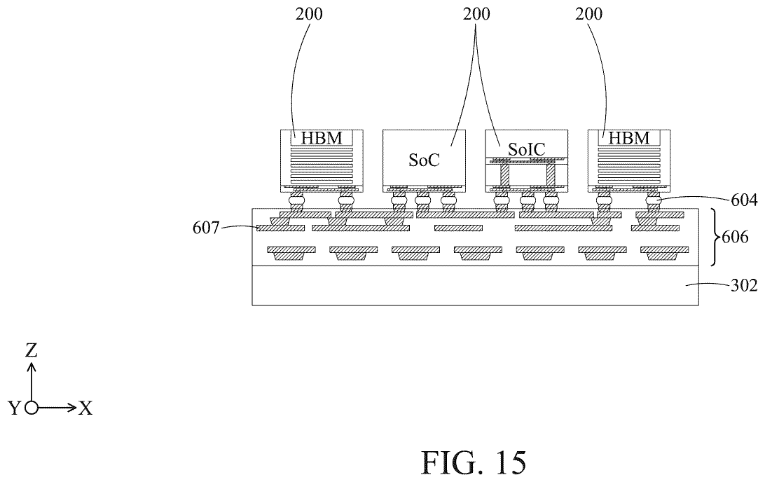

Referring to FIG. 15, the method 1000 at operation 1004 attaches dies (e.g., dies 200) onto the interposer structure (e.g., interposer 606). As shown, multiple dies 200 are bonded to the interposer 606 via the micro-bumps 604. The multiple dies 200 may be formed in a separate manufacturing process that includes forming device structures on a wafer and dicing the wafer into chips. The chips may then be processed to form the different dies 200.

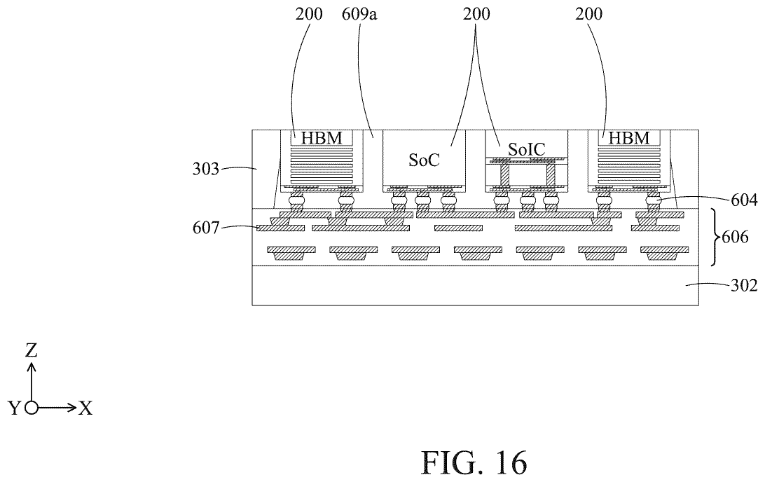

Referring to FIG. 16, the method 1000 at operation 1006 forms an underfill (e.g., underfill 609a) to fill gaps between the dies 200 and between the dies 200 and the interposer 606. Thereafter, as part of operation 1006, the method 1000 may form a molding compound 303 on the interposer 606. The molding compound laterally surrounds the underfill 609a. At the end of operation 1006, top surfaces of the dies 200 are exposed, and the top surfaces of the dies 200 may be substantially coplanar with top surfaces of the underfill 609a and the molding compound 303.

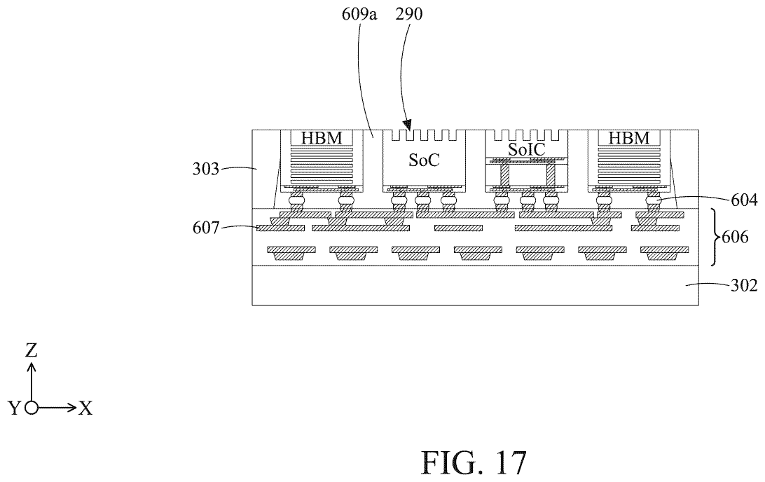

Referring to FIG. 17, the method 1000 at operation 1008 forms heat dissipation channels 290 in the dies 200 by any suitable process described herein. For reasons previously described, the heat dissipation channels 290 may be selectively formed on certain dies 200 (e.g., SoC and SoIC dies) but not formed on certain other dies 200 (e.g., HBM dies).

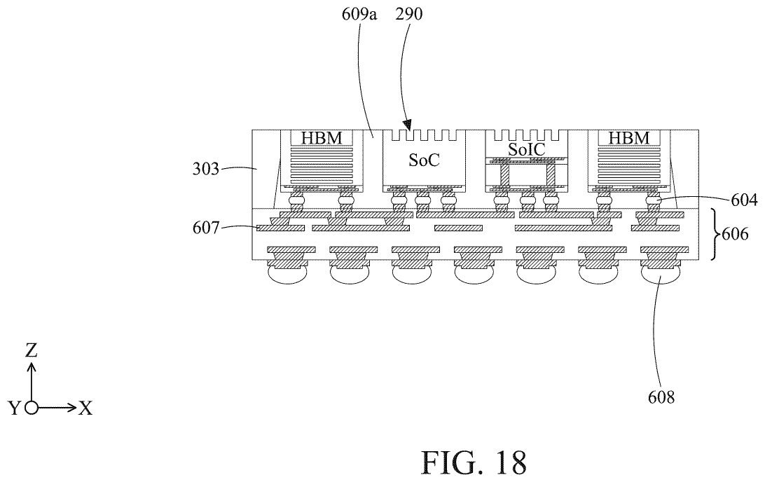

Referring to FIG. 18, the method 1000 at operation 1010 forms interconnect bumps (e.g., C4 bumps 608) on the interposer structure (e.g., interposer 606). The method 1000 at operation 1008 may include a bonding and/or a debonding process to attach/detach carrier substrates 302 for appropriate backside processing of the interposer structure. The backside processing may include etching back the interposer structure (e.g., interposer 606) to expose landing pads and/or conductive traces 607 and forming the C4 bumps 608 on the landing pads and/or conductive traces 607.

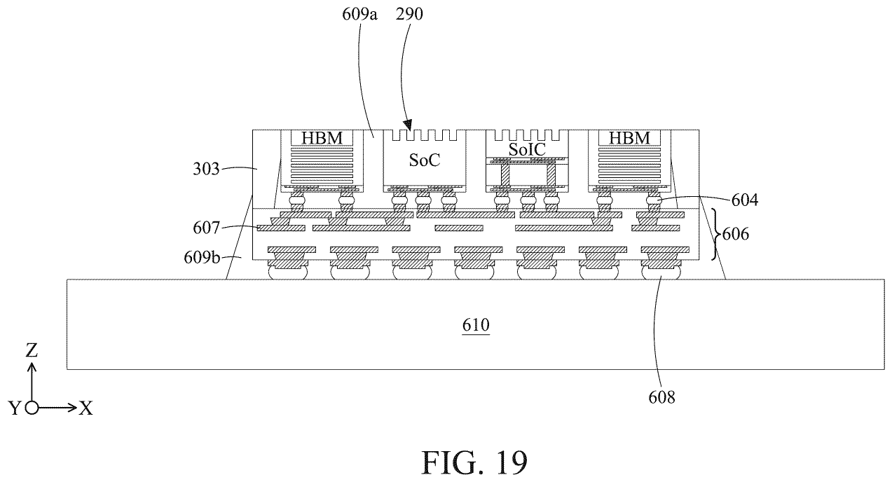

Referring to FIG. 19, the method 1000 at operation 1012 attaches the interposer structure (e.g., interposer 606) and dies 200 onto a package substrate 610. The interposer 606 may be attached via the C4 bumps 608 landing on and bonding to landing pads of the package substrate 610. Thereafter, as part of operation 1012, the method 1000 may form an underfill (e.g., underfill 609b) to fill gaps between the C4 bumps 608 dies 200 and between the interposer 606 and the package substrate 610. The underfill 609b laterally surrounds the interposer 606.

Referring to FIG. 20A, the method 1000 at operation 1014 dispenses a thermal interface material (TIM) layer (e.g., TIM layer 504) over the dies 200. The TIM layer 504 may be dispense by any suitable process and lands on top surfaces of the dies 200 and the underfill 609a. In some embodiments the TIM layer 504 further lands on top surfaces of the molding compound 303. In the embodiment shown in FIG. 20A, the TIM layer 504 is an elastic or liquid material that seeps into the heat dissipation channels 290. As shown, the TIM layer 504 completely or substantially fills the heat dissipation channels 290 for maximized surface contact. Alternatively, referring to FIG. 20B, the TIM layer 504 only partially seeps into and does not substantially fill the heat dissipation channels 290. For example, in these cases, the TIM layer 504 requires the attachment of a lid to apply necessary force to push the TIM layer 504 into heat dissipation channels 290 for complete filling.

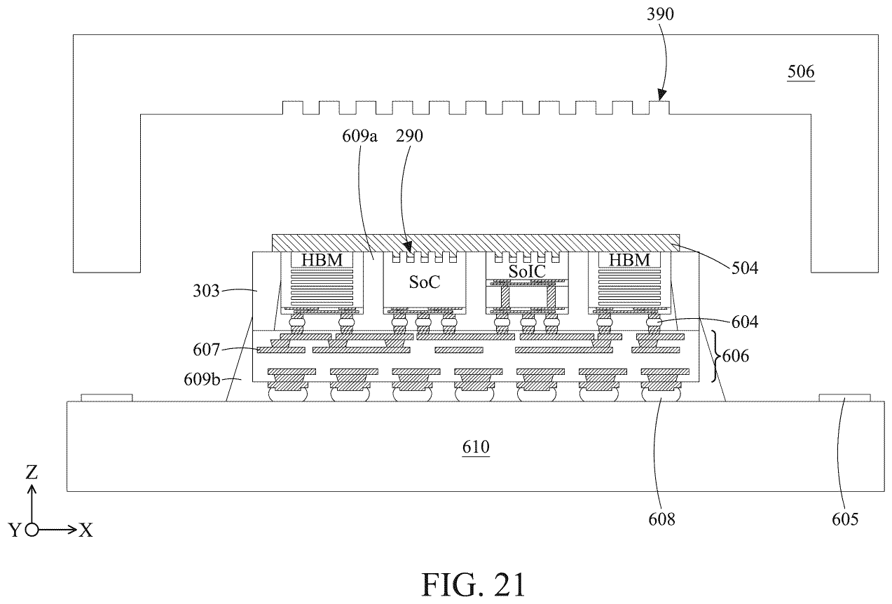

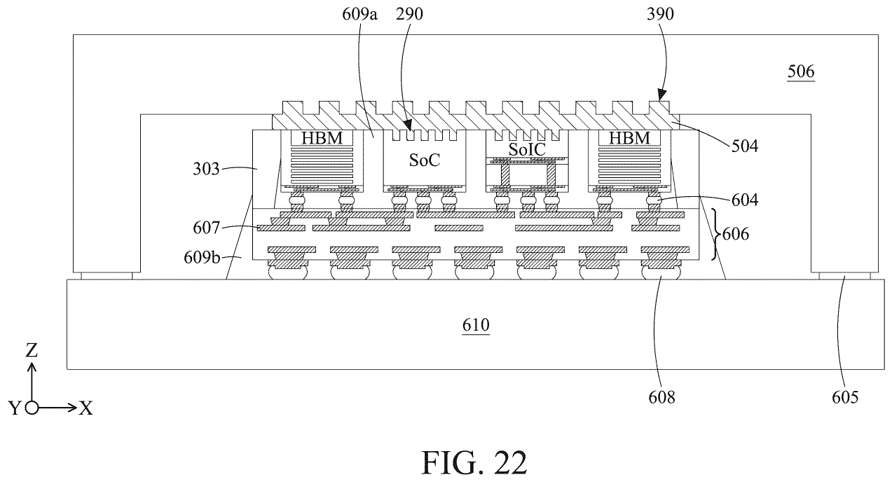

Referring to FIGS. 21-22, the method 1000 at operation 1016 places a lid (e.g., lid 506) over the TIM layer 504. Referring to FIG. 21, the lid 506 may include heat dissipation channels 390 formed over its bottom surface by a suitable process described herein. The heat dissipation channels 390 may be formed before the operation 1016. Referring to FIG. 22, the lid 506 is placed and mounted over the TIM layer 504 via base adhesive joints 605. The base adhesive joints 605 are formed over the package substrate 610. When the lid 506 is secured, the lid 506 may provide a level of compression onto the TIM layer 504 to ensure the TIM materials in the TIM layer 504 stays in place and/or completely fills into the heat dissipation channels 290/390 for maximize thermal surface contact. In the embodiment of FIG. 20A, the TIM layer 504 may already completely fill the heat dissipation channels 290. In this case, when the lid 506 is attached, the lid 506 ensures the TIM layer 504 stays in place and that the TIM layer 504 completely fills the heat dissipation channels 390. On the other hand, in the embodiment of FIG. 20B, the TIM layer 504 requires the attachment of the lid 506 to apply necessary force to push the TIM layer 504 into heat dissipation channels 290/390 for complete filling. In any case, after lid attachment, the TIM layer 504 includes protruding portions that penetrate into the dies 200 and/or into the lid 506 and planar portions disposed between the protruding portions. In some cases, when the TIM layer 504 is compressed or thermally stressed, the TIM layer 504 may expand laterally in the y direction. As such, in the embodiment shown in FIG. 5, additional heat dissipation channels 490 may be formed to catch the laterally expanded TIM layer 504 and to avoid any TIM leakage or loss.

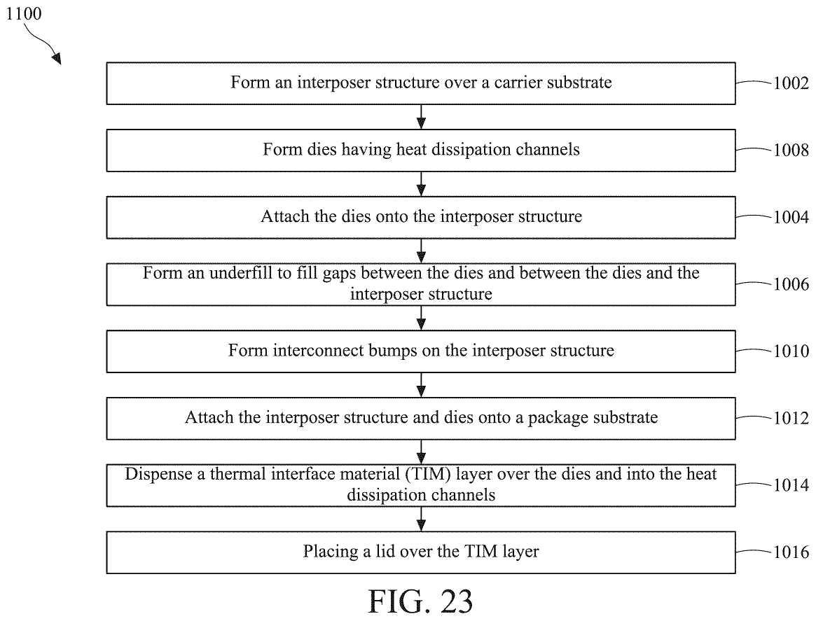

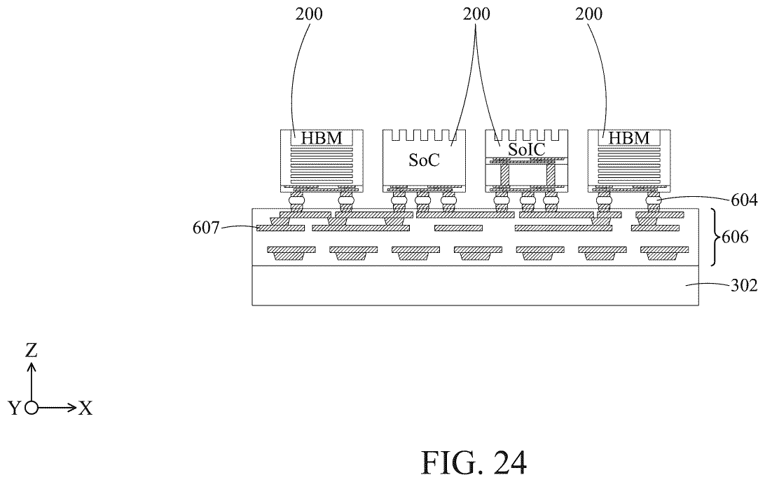

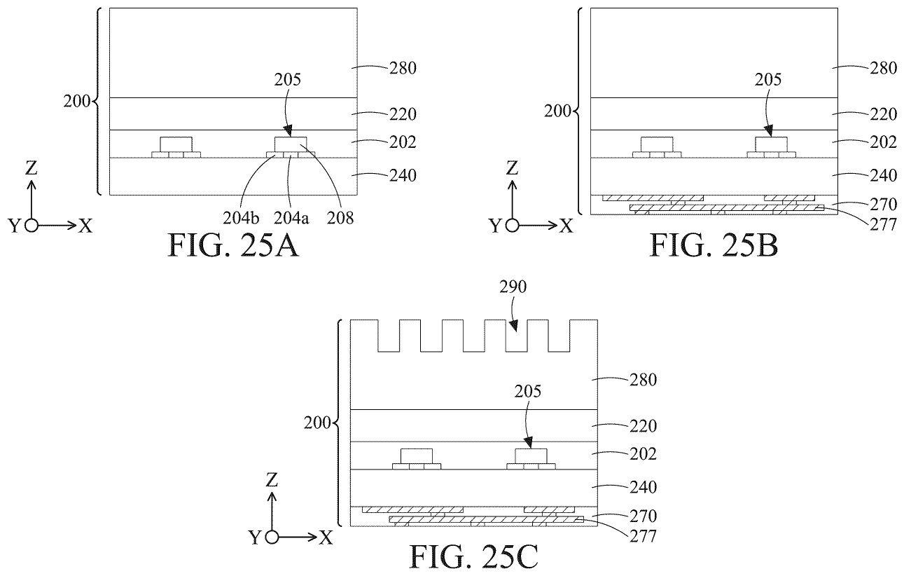

FIG. 23 illustrates a flow chart of a method 1100 to form an IC semiconductor package 100 having heat dissipation channels 290 for improved thermal distribution, in portion or in entirety, according to another embodiment of the present disclosure. FIGS. 24 and FIGS. 25A-25C illustrate an IC semiconductor package 100 (or a portion thereof) at intermediate stages of fabrication and processed in accordance with the method of FIG. 23, according to an embodiment of the present disclosure. Method 1100 is merely an example and is not intended to limit the present disclosure to what is explicitly illustrated. Additional steps can be provided before, during and after method 1100 and some steps described can be replaced, eliminated, or moved around for additional embodiments of the method. Not all steps are described herein in detail for reasons of simplicity. Method 1100 is described below in conjunction with FIGS. 24 and 25A-25C. Similar features previously described may equally apply to features shown in FIGS. 24 and 25A-25C. As such, not all features in FIGS. 24 and 25A-25C are described herein in detail for reasons of simplicity.

The method 1100 is similar to the method 1000, and the similar method steps will not be described again for the sake of brevity. The difference is in when the heat dissipation channels 290 are formed. In the method 1000, the heat dissipation channels 290 are formed after the dies 200 are attached and bonded to the interposer 606. Whereas, in the method 1100, the heat dissipation channels 290 are formed as part of forming the dies 200, and thus they are formed before the dies 200 are attached and bonded to the interposer 606.

Referring to FIG. 24, the method 1100 first form dies 200 having heat dissipation channels 290 (see operation 1008), then the method 1100 attaches the dies 200 having heat dissipation channels 290 onto the interposer 606 (see operation 1004). After the dies 200 are attached, the method 1100 may perform similar operations as in method 1000 to complete fabrication of the semiconductor package 100.

Referring to FIGS. 25A-25C, the method 1100 at operation 1008 may form heat dissipation channels 290 in a die 200 through several steps. Although described with respect to method 1100, the physical features of the die 200 in FIGS. 25A-25C also expounds on other portions of the present disclosure. Referring to FIG. 25A, the die 200 may be first formed to have a device layer 202, a frontside interconnect structure 220 over the device layer 202, a backside interconnect structure 240 under the device layer 202, and a carrier substrate 280 over the frontside interconnect structure 220.

The device layer 202 is where device-level features such as transistor devices 205 are formed. Each of the transistor devices includes a channel region 204a between source/drain (S/D) regions 204b and a gate stack 208 over the channel regions 204a. The device layer 202 may further include other device-level features such as S/D contacts, S/D vias, gate contacts, and/or gate vias, each of which may electrically connect the S/D regions and/or the gate stacks to a higher material layer (e.g., frontside interconnect structure 220 or lower material layer (e.g., backside interconnect structure 240) of the die 200.

The frontside interconnect structure 220 and the backside interconnect structure 240 each include metal lines and vias embedded in an intermetal dielectric (IMD) layer. The metal lines and vias route signals from the transistor devices 205 to desired locations in the die 200 and to redistribution layers (e.g., RDL 270) for external connections.

The carrier substrate 280 provides structural support in preparation for backside processing (e.g., the carrier substrate 280 is formed prior to forming the backside interconnect structure 220/RDL 270). The carrier substrate 280 may include silicon (Si), or other semiconductor materials such as germanium (Ge), silicon carbide (SiC), silicon germanium (SiGe), or diamond. Note that in some embodiments, the carrier substrate 280 may be bonded to the frontside interconnect structure 220 through a bonding layer therebetween. The bonding layer may be a metal bonding layer, an oxide bonding layer, or a bonding layer having a hybrid of metal and oxide.

Referring to FIG. 25B, the die 200 may then be further formed to have an RDL 270 (e.g., below the backside interconnect structure 240). The RDL 270 includes conductive traces 277 embedded in one or more passivation layers, and the conductive traces 277 route signals to external circuitry (e.g., interposer 606).

Referring to FIG. 25C, the heat dissipation channels 290 may then be formed through a sawing/cutting process or any other process described herein. As shown, the heat dissipation channels 290 may cut into the carrier substrate 280 of the die 200. In further embodiments, the heat dissipation channels 290 may cut even deeper, such as into a bonding layer, or even portions of the frontside interconnect structure 220. The heat dissipation channels 290 may cut into dies 200 as long as the performance of the dies 200 are not negatively affected. Thereafter, the die 200 (which previously may be part of a wafer) may be singulated through another sawing/cutting process.

Although not limiting, the present disclosure offers advantages for semiconductor packages. One example advantage is to incorporate heat dissipation channels in top dies for improved thermal contact. Another example advantage is to further incorporate heat dissipation channels in the lid. Another example advantage is to further incorporate heat dissipation channels in peripheral regions adjacent the top dies. Another example advantage is to ensure TIM material completely fills into the heat dissipation channels via proper fill material and via compression from the lid. Another example advantage is providing various types of heat dissipation channels in the dies and formed in various ways according to design needs.

One aspect of the present disclosure pertains to a package structure. The package structure includes a die bonded to a substrate, where a plurality of first channels are formed on a top surface of the die; a lid bonded to the substrate and over the die; and a thermal interface material (TIM) disposed between and contacting the lid and the dic, where the thermal interface material fills the first channels.

In an embodiment, the lid interfaces the TIM along a substantially coplanar surface. In an embodiment, a plurality of second channels are formed on a bottom surface of the lid, the second channels facing the first channels, and the TIM also fills the second channels.

In an embodiment, the plurality of first channels form first grooves that extend lengthwise across the top surface of the die along a first direction. In a further embodiment, the first grooves extend an entire length of the die along the first direction. In a further embodiment, the plurality of first channels form second grooves that extend lengthwise across the top surface of the die along a second direction perpendicular to the first direction. In an embodiment, the second grooves extend an entire width of the die along the second direction.

In an embodiment, the package structure further includes an interposer structure between the die and the substrate, where the die is bonded to the interposer structure via first interconnect bumps, and the interposer structure is bonded to the substrate via second interconnect bumps.

In an embodiment, the die is a first die, and the package structure further includes a second die bonded to the substrate, where the TIM is disposed between and contacting the lid and the second die, wherein the second die has a substantially coplanar top surface. In an embodiment, the top surface of the first die has a first surface area, the top surface of the second die has a second surface area, and the first surface area is greater than the second surface area. In an embodiment, the first die is a system-on-chip (SoC) die and the second die is a memory die.

Another aspect of the present disclosure pertains to a semiconductor package. The semiconductor package includes a die bonded to a substrate, where the die includes first cavities that cut into a top surface of the die; a thermal interface material (TIM) filling the first cavities and covering the top surface of the die; and a lid over the TIM, where the lid includes second cavities that cut into a bottom surface of the lid, where the TIM fills the second cavities.

In an embodiment, the semiconductor package further includes an interposer structure between the die and the substrate, where the die is bonded to the interposer structure via first interconnect bumps, and the interposer structure is bonded to the substrate via second interconnect bumps, where the lid lands on the substrate and surrounds side surfaces of the die and the interposer structure.

In an embodiment, from a top view, the die has a die width along a first direction and a die length along a second direction perpendicular to the first direction. The first cavities form grooves that extend lengthwise across the top surface of the die along the second direction. In a further embodiment, the grooves have a groove width along the first direction and a groove length along the second direction, and the groove length is greater than the groove width. In an embodiment, the grooves have a groove width along the first direction, and a ratio of the groove width to the die width ranges between about 0.01% to about 5%.

In an embodiment, from a top view, the die spans a first area, and the first cavities collectively spans a second area in the first area, wherein a ratio of the first area to the second area ranges between about 5% to about 90%.

Another aspect of the present disclosure pertains to a method of forming a semiconductor package. The method includes attaching dies onto an interposer structure;

forming an underfill to fill gaps between the dies and between the dies and the interposer structure; forming grooves in the dies to form heat dissipation channels on a top surface of the dies; attaching the interposer structure onto a substrate; dispensing a thermal interface material (TIM) layer over the dies; and placing a lid over the TIM layer, where the TIM layer fills the heat dissipation channels.

In an embodiment, the grooves are formed after the dies are attached onto the interposer structure. In an embodiment, the placing of the lid compresses the TIM layer such that the TIM layer seeps into and conforms to a shape of the grooves.

The details of the method and device of the present disclosure are described in the attached drawings. The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a die bonded to a substrate, wherein a plurality of first channels are formed on a top surface of the die;
a lid bonded to the substrate and over the die; and
a thermal interface material (TIM) disposed between and contacting the lid and the die, wherein the thermal interface material fills the first channels.

2. The package structure of claim 1, wherein the lid interfaces the TIM along a substantially coplanar surface.

3. The package structure of claim 1, wherein a plurality of second channels are formed on a bottom surface of the lid, the second channels facing the first channels, and the TIM also fills the second channels.

4. The package structure of claim 1, wherein the plurality of first channels form first grooves that extend lengthwise across the top surface of the die along a first direction.

5. The package structure of claim 4, wherein the first grooves extend an entire length of the die along the first direction.

6. The package structure of claim 4, wherein the plurality of first channels form second grooves that extend lengthwise across the top surface of the die along a second direction perpendicular to the first direction.

7. The package structure of claim 6, wherein the second grooves extend an entire width of the die along the second direction.

8. The package structure of claim 1, further comprising:
an interposer structure between the die and the substrate, wherein the die is bonded to the interposer structure via first interconnect bumps, and the interposer structure is bonded to the substrate via second interconnect bumps.

9. The package structure of claim 1, wherein the die is a first die, further comprising:
a second die bonded to the substrate, wherein the TIM is disposed between and contacting the lid and the second die, wherein the second die has a substantially coplanar top surface.

10. The package structure of claim 9, wherein the top surface of the first die has a first surface area, the top surface of the second die has a second surface area, and the first surface area is greater than the second surface area.

11. The package structure of claim 9, wherein the first die is a system-on-chip (SoC) die and the second die is a memory die.

12. A semiconductor package, comprising:
a die bonded to a substrate, wherein the die includes first cavities that cut into a top surface of the die;
a thermal interface material (TIM) filling the first cavities and covering the top surface of the die; and
a lid over the TIM, wherein the lid includes second cavities that cut into a bottom surface of the lid, wherein the TIM fills the second cavities.

13. The semiconductor package of claim 12, further comprising:
an interposer structure between the die and the substrate, wherein the die is bonded to the interposer structure via first interconnect bumps, and the interposer structure is bonded to the substrate via second interconnect bumps, wherein the lid lands on the substrate and surrounds side surfaces of the die and the interposer structure.

14. The semiconductor package of claim 12,
wherein from a top view, the die has a die width along a first direction and a die length along a second direction perpendicular to the first direction,
wherein the first cavities form grooves that extend lengthwise across the top surface of the die along the second direction.

15. The semiconductor package of claim 14, wherein the grooves have a groove width along the first direction and a groove length along the second direction, and the groove length is greater than the groove width.

16. The semiconductor package of claim 14, wherein the grooves have a groove width along the first direction, and a ratio of the groove width to the die width ranges between about 0.01% to about 5%.

17. The semiconductor package of claim 12, wherein from a top view, the die spans a first area, and the first cavities collectively spans a second area in the first area, wherein a ratio of the first area to the second area ranges between about 5% to about 90%.

18. A method of forming a semiconductor package, comprising:
attaching dies onto an interposer structure;
forming an underfill to fill gaps between the dies and between the dies and the interposer structure;
forming grooves in the dies to form heat dissipation channels on a top surface of the dies;
attaching the interposer structure onto a substrate;
dispensing a thermal interface material (TIM) layer over the dies; and
placing a lid over the TIM layer,
wherein the TIM layer fills the heat dissipation channels.

19. The method of claim 18, wherein the grooves are formed after the dies are attached onto the interposer structure.

20. The method of claim 18, wherein the placing of the lid compresses the TIM layer such that the TIM layer seeps into and conforms to a shape of the grooves.
